(19) United States
(12) Patent Application Publication
(10) Pub. No.: US 2012/0048373 A1
(43) Pub. Date: Mar. 1, 2012

(54) SEALING MATERIAL FOR SOLAR CELL AND SOLAR CELL MODULE INCLUDING SAME

(76) Inventors: Nam-Choul Yang, Yongin-si (KR); Do-Young Park, Yongin-si (KR); Si-Young Cha, Yongin-si (KR); Yi-Hyun Chang, Yongin-si (KR)

(21) Appl. No.: 13/073,934

(22) Filed: Mar. 28, 2011

(30) Foreign Application Priority Data
Aug. 30, 2010 (KR) 10-2010-0084242

(51) Int. Cl. H01L 31/0203; H01L 31/18; C08F 255/02

(52) U.S. Cl. 136/259; 525/285; 438/64; 257/E31.117

(57) ABSTRACT

A sealing material for a solar cell and a solar cell including the same, and the sealing material includes a polymer resin having a vicat softening point at 100° C. or 130° C. or between 100° C. and 130° C.

### CROSS-REFERENCE TO RELATED APPLICATION

This application claims priority to and the benefit of Korean Patent Application No. 10-2010-0084242, filed in the Korean Intellectual Property Office on Aug. 30, 2010, the entire content of which is incorporated herein by reference.

### BACKGROUND

1. Field

This disclosure relates to a sealing material for a solar cell and a solar cell module including the same.

2. Description of Related Art

Use of solar cell modules, also referred to as photovoltaic cell modules, (hereinafter, “solar cells”) as renewable energy sources are rapidly spreading. As solar cells have become more and more complicated, there has been an increasing demand for a sealant (sealing material) having improved performance.

A unit cell of a general dye sensitized solar cell includes upper and lower transparent substrates, conductive transparent electrodes respectively formed on the surface of the transparent substrates, a transition metal oxide porous layer with dye absorbed on the surface that is formed on one conductive transparent electrode corresponding to a first electrode, a catalyst thin film electrode that is formed on the other conductive transparent electrode corresponding to a second electrode, and an electrolyte filled between the transition metal oxide (for example TiO₂) porous electrode and the catalyst thin film electrode.

Specifically, the dye sensitized solar cell uses the electrolyte as a hole transport medium, and electrolyte dependence of the dye sensitized solar cell is dependent upon diffusion rate of the electrolyte. Further, a liquid state organic solvent electrolyte or ionic liquid electrolyte has a larger diffusion rate than a semi-solid type or a solid type. Thus, such liquid state organic solvent electrolyte or ionic liquid electrolyte has excellent photoelectric conversion efficiency.

However, the liquid electrolyte tends to evaporate according to the outside temperature and environment, and generates leakage to deteriorate performance of the dye sensitized solar cell. Thus, leakage prevention of the electrolyte solution is required, and the leakage is generated mostly at an incompletely sealed part. Conventional dye sensitized solar cell sub-modules are generally sealed by heating a resin or inorganic adhesive.

However, in this case, due to a large difference between thermal expansion coefficients of a glass substrate and the sealant, it is difficult to secure complete air-tightness, and the resin may have a reduced life-span due to its inferior chemical resistance and durability.

Accordingly, in order to improve the adhesion strength of the sealant and improve chemical resistance and durability so as to prevent defects of the sealed part, improvement of the sealant is required.

### SUMMARY OF THE INVENTION

An aspect of an embodiment is directed toward a sealing material for a solar cell having excellent characteristics. Another aspect of an embodiment is directed toward a solar cell having excellent long term reliability characteristics.

According to an embodiment, a sealing material for a solar cell including a polymer resin having a vicat softening point at 100° C. or 130° C. or between 100° C. and 130° C. is provided.

The polymer resin may include a maleic anhydride grafted polyolefin.

The polymer resin may include a maleic anhydride grafted high density polyethylene, a medium density polyethylene, a linear low density polyethylene, or a combination thereof.

The maleic anhydride grafted high density polyethylene may have a density at 0.91 g/cm³ or 0.97 g/cm³ or between 0.91 g/cm³ and 0.97 g/cm³.

The sealing material may have adhesion strength to glass at 5 kgf/cm² or 7 kgf/cm² or between 5 kgf/cm² and 7 kgf/cm².

According to another embodiment, a solar cell includes a light receiving substrate; a rear substrate spaced apart from the light receiving substrate and electrically connected with the light receiving substrate; and a sealing material between the light receiving substrate and the rear substrate and on both lateral sides of the solar cell. Here, the sealing material includes a polymer resin having a vicat softening point at 100° C. or 130° C. or between 100° C. and 130° C.

The polymer resin may include a maleic anhydride grafted polyolefin.

The polymer resin may include a maleic anhydride grafted high density polyethylene, a medium density polyethylene, a linear low density polyethylene, or a combination thereof.

The maleic anhydride grafted high density polyethylene may have a density at 0.91 g/cm³ or 0.97 g/cm³ or between 0.91 g/cm³ and 0.97 g/cm³.

The sealing material may have an adhesion strength to a substrate at 5 kgf/cm² or 7 kgf/cm² or between 5 kgf/cm² and 7 kgf/cm².

The sealing material may be formed by heating at 120° C. or 200° C. or between 120° C. and 200° C. utilizing a pressure heating method or a local heating method.

In one embodiment of the present invention and by providing a sealing material having a high vicat softening point as described above, a solar cell having excellent long term reliability is prepared.

### BRIEF DESCRIPTION OF THE DRAWING

FIG. 1 is a graph showing current densities by voltage of Example 2 and Comparative Examples 2 and 3.

FIG. 2 is a schematic view illustrating a solar cell pursuant to an embodiment of the present invention.

### DETAILED DESCRIPTION OF THE EMBODIMENTS

Exemplary embodiments of the present invention will hereinafter be described in more detail. However, these embodiments are only exemplary, and the present invention is not limited thereto.

In a solar cell module (hereinafter, “solar cell”), the vicat softening point of a sealing material is an important characteristic in an aspect of long-term reliability. For example, dye sensitized solar cells have recently followed JIS C8938 which is a regulation for evaluation of accelerated life-span reliability, wherein an evaluation condition of accelerated life span is about 85° C. to about 90° C.

Therefore, a sealing material of a solar cell should have a range of vicat softening point of higher than the upper limit of the above temperature range in order to have a good long life-span characteristic even under severe conditions.

Another important characteristic of a sealing material is adhesion strength to a substrate. If a sealing material has low adhesion strength, an adhesive layer should be separately formed for adhesion of the sealing material, which may be inconvenient.

One embodiment provides a sealing material for a solar cell including a polymer resin having a vicat softening point at 100° C. or 130° C. or between 100° C. and 130° C.

In one embodiment, a sealing material having a vicat softening point in the above range, if used as a sealing material for a solar cell, extends (or does not limit) the life-span characteristic of the solar cell.

The polymer resin may include a maleic anhydride grafted polyolefin.

Examples of the grafted polyolefin may include a maleic anhydride grafted high density polyethylene, a medium density polyethylene, a linear low density polyethylene, or the like.

In one embodiment, the maleic anhydride grafted high density polyethylene has a density at 0.91 g/cm³ or 0.97 g/cm³ or between 0.91 g/cm³ and 0.97 g/cm³ In one embodiment, if the sealing material has high density in the above range, adhesion strength of the sealing material is improved, and chemical resistance and durability is also improved.

In one embodiment, the sealing material has an adhesion strength to a substrate at 5 kgf/cm² or 7 kgf/cm² or between 5 kgf/cm² and 7 kgf/cm². Examples of the substrate may include a transparent conductive oxide coated glass, a frit-coated substrate, a metal foil (Ti, W, Mo, Al), a plastic or transparent conductive layer coated plastic, or the like.

In one embodiment, since the sealing material has the above characteristics, the sealing material has relatively good adhesion strength to the upper or lower substrate, and the sealing material is useful as a sealing material for a solar cell.

The polymer resin may further include any suitable additives. Examples of the additives may include a plasticizer, a treatment aid, a fluidity improving additive, a lubricant, pigment, a dye, a flame retardant, an impact controller, a nucleating agent for increasing crystallinity, an anti-blocking agent such as silica, a hindered amine light stabilizer (HALS), an ultraviolet (UV) stabilizer, a dispersing agent, a surfactant, a chelating agent, a coupling agent, an adhesive, a primer, a reinforcing additive (e.g., glass fiber), a filler, or the like, but is not limited thereto.

In general, the HALS includes a secondary, tertiary, acetylated, N-hydrocarbyloxy substituted, hydroxyl substituted, N-hydrocarbyloxy substituted, or other substituted cyclic amine, or the like, which further has steric hindrance generally derived from an aliphatic substituent on a carbon atom adjacent to an amine functional group. The HALS may be included in a maximum amount of about 10 wt %, about 5 wt %, or about 1 wt %, based on the total weight of the polymer resin.

Another embodiment provides a solar cell having a light receiving substrate on one side and a rear substrate on the other side, the substrates being electrically connected with each other, the solar cell including a sealing material that is formed on both lateral sides of the solar cell, and is vertically formed to the light receiving substrate and the rear substrate, and the sealing material including a polymer resin having a vicat softening point of at 100° C. or 130° C. or between 100° C. and 130° C.

In one embodiment, the polymer resin and the sealing material are the same as described above, and the same explanations thereof are not provided again.

The light receiving substrate may be formed of transparent material, and is preferably formed of material having high light transmittance. For example, the light receiving substrate may be formed as a glass substrate made of a glass material or a resin film. The resin film is suitable for applications requiring flexibility because it commonly has flexibility.

Although the rear substrate oppositely disposed to (or disposed to face) the light receiving substrate does not particularly require transparency, it may be formed of a transparent material so the solar cell may receive light (VL) on both sides for increasing photoelectric conversion efficiency, and the rear substrate may be formed of the same material as the light receiving substrate. Particularly, in case the solar cell (or photoelectric conversion device) is used for BIPV (building integrated photovoltaics) installed on a structure such as a window frame, it is preferable that both sides of the photoelectric conversion device have transparency so as to not block light (VL) flowing indoors.

A sealing material for a solar cell according to one embodiment exhibits satisfactory adhesion strength to the light receiving substrate or the rear substrate.

The sealing material may be formed by heating at about 120° C. to about 200° C. using a pressure heating method or a local heating method. This is to maximally reduce heat damage to organic compounds and the like in a solar cell (e.g., dye sensitized solar cell). However, this heating is not limited to the local heating, and entire heating may also be used.

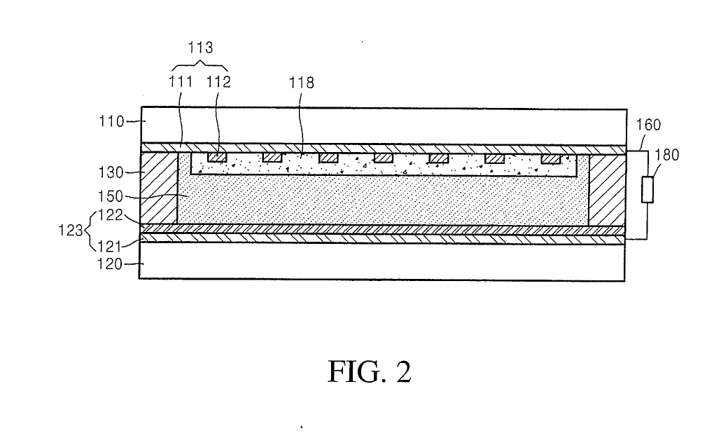

Referring to FIG. 2, a solar cell includes a light receiving substrate 110 and a rear substrate 120 that are spaced apart from each other with a sealing material 130 interposed therebetween. In one embodiment as shown in FIG. 2, the sealing material 130 is formed on both lateral sides of the solar cell. In addition, a first electrode 113 may be disposed on an inner surface of the light receiving substrate 110 (i.e., on the surface facing the rear substrate 120 ), and a second electrode 123 may be disposed on an inner surface of the rear substrate 120 (i.e., on the surface facing the light receiving substrate 110 ). A semiconductor layer 118 may be disposed on the light receiving substrate electrode 113, and an electrolyte layer 150 may be interposed between the semiconductor layer 118 and the second electrode 123. The first electrode 113 may include a first transparent conductive layer 111 and mesh-patterned grid electrodes 112 formed on the first transparent conductive layer 111. The second electrode 123 may include a second transparent conductive layer 121 and a catalyst layer 122 formed on the second transparent conductive layer 121. The first electrode 113 and the second electrode 123 may be electrically connected to each other through a conductive wire 160 and an external circuit 180. Here, the structure of the solar cell of FIG. 2 is only an example and may suitably vary.

In the above embodiment, a solar cell may be generally used in various suitable fields and optimized. In one embodiment, a solar cell includes any article capable of converting light into electrical energy. Examples of typical technical fields of solar cells of various forms may include a single crystalline silicon solar cell, a polysilicon solar cell, a microcrystalline silicon solar cell, an amorphous silicon based solar cell, a copper indium selenide solar cell, a compound semiconductor solar cell, a dye sensitized solar cell, or the like, but are not limited thereto. Most common types of solar cells may include a polycrystalline solar cell, a thin film solar cell, a compound semiconductor solar cell, and an amorphous solar cell.

A thin film solar cell is prepared by depositing several thin film layers on a substrate such as a glass or flexible film while patterning the layers so as to form multiple separate units that are electrically connected with each other to produce a suitable voltage output. According to the order of performing multi-layer deposition, the substrate may function as a rear substrate or a front window of the solar cell. Examples of the thin film solar cell may include a cadmium telluride or a CIGS (Cu(InGa)(SeS)₂) thin film battery.

Yet another embodiment provides a solar cell having a light receiving substrate on one side and a rear substrate on the other side, the substrates being electrically connected with each other, the solar cell including a sealing material that is formed on both lateral sides of the solar cell and is vertically formed to the light receiving substrate and the rear substrate, and this sealing material including a polymer resin having a vicat softening point of at 100° C. or 130° C. or between 100° C. and 130° C.

In one embodiment, the polymer resin and the sealing material are the same as described above, and the same explanations thereof are not provided again.

A manufacturing process of the solar cell is briefly explained as follows. Along the periphery of a space between the light receiving substrate and the rear substrate, a sealing material is interposed, and set or predetermined pressure and heat are applied to seal both substrates with each other, thereby forming a substrate gap of an appropriate size between the substrates. The substrate gap is filled with an electrolyte.

As the electrolyte, a redox electrolyte including a pair of an oxidant and a reductant may be used, and a solid type electrolyte, a gel phase electrolyte, a liquid type electrolyte, or the like may be used.

Hereinafter, the embodiments are illustrated in more detail with reference to examples. However, the following are exemplary embodiments and are not limiting.

### EXAMPLE

### Preparation of Sealing Material

### Example 1

As a sealing material, Bynel 4003 of DuPont Company is used.

Bynel 4003 is a high density polyethylene compound grafted with a maleic anhydride of DuPont Company. The Bynel 4003 has a density of about 0.95 g/cm³.

### Comparative Example 1

As sealing material, Surlyn 1702 of DuPont Company is used.

The Surlyn 1702 is a copolymer compound of ethylene and methacrylic acid of DuPont Company.

### Fabrication of Device

### Example 2

### Fabrication of Device

As a light receiving substrate and a rear substrate, soda-lime glass is used, and as a sealing material, the compound of Example 1 is used. As an electrolyte, a redox electrolyte is used.

The sealing material is interposed along the periphery of the space between the light receiving substrate and the rear substrate, and set or predetermined heat of about 120° C. to about 200° C. is locally applied to seal both substrates to each other.

Then, a solar cell is prepared according to a suitable manufacturing method of a solar cell.

### Comparative Example 2

### Fabrication of Device

A solar cell is prepared substantially by the same method as Example 2, except that the compound of Comparative Example 1 is used instead of that of Example 1 and a hot press including a heating plate is used instead of local heating.

The hot press application conditions include a temperature of about 150° C., a pressure of about 0.5 kgf/cm², and a time period of about 20 seconds to about 60 seconds.

### Comparative Example 3

### Fabrication of Device

A solar cell is prepared substantially by the same method as Example 2, except that the compound of Comparative Example 1 is used instead of that of Example 1 and laser heating is used instead of local heating.

The laser heating is performed by positioning the sealing material on the upper substrate and the lower substrate, and then pressing a quartz plate on top of the upper substrate to concurrently or simultaneously apply a pressure while being irradiated by a NdYAG laser (at 1064 nm wavelength) to the place the sealing material is located to adhere it.

### Experimental Example

### Comparison of Physical Properties

The following Table 1 compares physical properties of Example 1 and Comparative Example 1.

It can be seen that Example 1 has a significantly higher melting point, freezing point, and vicat softening point than Comparative Example 1.

TABLE 1

| | Unit | Comparative Example 1 | Example 1 |
|---|---|---|---|
| Melt index | dg/minute | 1.4 | 1.3 |
| Density | g/cm³ | 0.95 | 0.95 |
| Melting point | ° C. | 93 | 136 |
| Freezing point | ° C. | 64 | 115 |
| Vicat Softening point | ° C. | 65 | 129 |

### Comparison Experiment of Adhesion Strength to Glass

Adhesion strength experiments of Example 1 and Comparative Example 1 to glass are performed. As the glass, soda-lime glass is used.

To measure adhesion strength, peel-off experiments for the glass are performed.

The film of Comparative Example 1 (thickness of about 100 μm) is measured 5 times to determine average adhesion strength of about 2.5 kgf/cm (measurement data: 1.27, 2.69, 2.40, 3.71, 2.20), and the film of Example 1 (thickness of about 100 μm) is measured 5 times to determine average adhesion strength of about 6.9 kgf/cm (measurement data: 6.34, 7.18, 7.19, 6.40, 7.44).

### Comparison Experiment of Device Characteristic

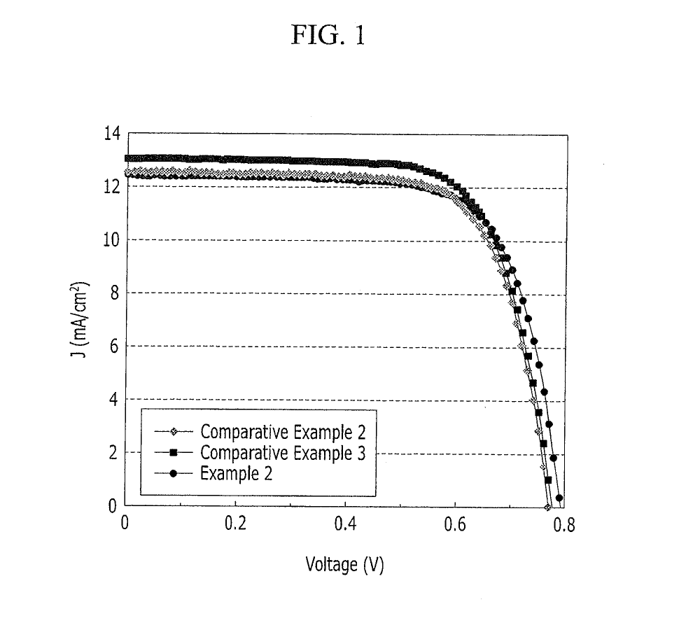

Current densities per voltage of the solar cells fabricated using Example 2 and Comparative Example 2 and 3 are measured. The measurement results are as shown in FIG. 1.

As shown in FIG. 1, characteristic of the device of Example 2 fabricated by the local heating method using the sealing material of Example 1 is corresponded to those of the devices of Comparative Examples 2 and 3 fabricated by the conventional method, and at a specific section, the device of Example 2 has excellent characteristics.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A sealing material for a solar cell comprising a polymer resin having a vicat softening point at 100° C. or 130° C. or between 100° C. and 130° C.

2. The sealing material for the solar cell of claim 1, wherein the polymer resin comprises a maleic anhydride grafted polyolefin.

3. The sealing material for the solar cell of claim 1, wherein the polymer resin comprises a maleic anhydride grafted high density polyethylene, a medium density polyethylene, a linear low density polyethylene, or a combination thereof.

4. The sealing material for the solar cell of claim 3, wherein the maleic anhydride grafted high density polyethylene has a density at 0.91 g/cm³ or 0.97 g/cm³ or between 0.91 g/cm³ and 0.97 g/cm³.

5. The sealing material for the solar cell of claim 1, wherein the sealing material has an adhesion strength to a substrate at 5 kgf/cm² or 7 kgf/cm² or between 5 kgf/cm² and 7 kgf/cm².

6. A solar cell comprising
a light receiving substrate;
a rear substrate spaced apart from the light receiving substrate and electrically connected with the light receiving substrate; and
a sealing material between the light receiving substrate and the rear substrate and on both lateral sides of the solar cell,
wherein the sealing material comprises a polymer resin having a vicat softening point at 100° C. or 130° C. or between 100° C. and 130° C.

7. The solar cell of claim 6, wherein the polymer resin comprises a maleic anhydride grafted polyolefin.

8. The solar cell of claim 6, wherein the polymer resin comprises a maleic anhydride grafted high density polyethylene, a medium density polyethylene, a linear low density polyethylene, or a combination thereof.

9. The solar cell of claim 8, wherein the maleic anhydride grafted high density polyethylene has a density at 0.91 g/cm³ or 0.97 g/cm³ or between 0.91 g/cm³ and 0.97 g/cm³.

10. The solar cell of claim 8, wherein the sealing material is formed by heating at 120° C. or 200° C. or between 120° C. and 200° C. utilizing a pressure heating method.

11. The solar cell of claim 6, wherein the sealing material has an adhesion strength at 5 kgf/cm² or 7 kgf/cm² or between 5 kgf/cm² and 7 kgf/cm².

12. A method of forming a solar cell, the method comprising
providing a sealing material composed of a polymer resin having a vicat softening point at 100° C. or 130° C. or between 100° C. and 130° C.; and
interposing the sealing material between a light receiving substrate and a rear substrate and on both lateral sides of the solar cell.

13. The method of claim 12, wherein the polymer resin comprises a maleic anhydride grafted polyolefin.

14. The method of claim 12, wherein the polymer resin comprises a maleic anhydride grafted high density polyethylene, a medium density polyethylene, a linear low density polyethylene, or a combination thereof.

15. The method of claim 14, wherein the maleic anhydride grafted high density polyethylene has a density at 0.91 g/cm³ or 0.97 g/cm³ or between 0.91 g/cm³ and 0.97 g/cm³.

16. The method of claim 12, wherein the sealing material is formed by heating at 120° C. or 200° C. or between 120° C. and 200° C. utilizing a pressure heating method.

17. The method of claim 12, wherein the sealing material has an adhesion strength at 5 kgf/cm² or 7 kgf/cm² or between 5 kgf/cm² and 7 kgf/cm².
